(19) United States
(12) Patent Application Publication
(10) Pub. No.: US 2026/0182302 A1
(43) Pub. Date: Jun. 25, 2026

(54) APPARATUS AND SYSTEM FOR TRANSFERRING SUBSTRATE

(71) Applicant: SAMSUNG ELECTRONICS CO., LTD., Suwon-si (KR)

(72) Inventor: Hochan LEE, Suwon-si (KR)

(73) Assignee: SAMSUNG ELECTRONICS CO., LTD., Suwon-si (KR)

(21) Appl. No.: 19/240,953

(22) Filed: Jun. 17, 2025

(30) Foreign Application Priority Data
Dec. 23, 2024 (KR) 10-2024-0193573

(51) Int. Cl. H01L 21/677; B65G 47/90

(52) U.S. Cl. CPC H10P 72/3206; B65G 47/90

(57) ABSTRACT

A substrate transfer system includes a first substrate transfer apparatus configured to transfer a wafer carrier; and a second substrate transfer apparatus configured to transfer the wafer carrier, in which the first substrate transfer apparatus includes a first housing having a first opening and a second opening at a position different from the first opening in a first direction, and a first lifter configured to transfer the wafer carrier loaded into the first housing, and in which the second substrate transfer apparatus includes: a second housing having a third opening at a position that overlaps with the second opening in a second direction perpendicular to the first direction, and a fourth opening at a position different from the third opening in the first direction, and a second lifter configured to transfer the wafer carrier loaded into the second housing.

### CROSS-REFERENCE TO RELATED APPLICATION

This application claims priority to Korean Patent Applications No. 10-2024-0193573, filed in the Korean Intellectual Property Office on Dec. 23, 2024, the entire contents of which are hereby incorporated by reference.

### BACKGROUND

### 1. Field

The present disclosure relates to a substrate transfer apparatus and a substrate transfer system including the same.

### 2. Description of Related Art

A substrate transfer apparatus provides a substrate to or collects the substrate from processing equipment used in the processing, using a carrier loaded with a plurality of substrates such as, for example, a Front Opening Unified Pod (FOUP) or a Front Opening Shipping Box (FOSB).

Semiconductor manufacturing involves a series of different processes, and thus, can involve transfer to a variety of process equipment. In general, the processing equipment has a multi-level structure, requiring the substrate transfer apparatus to move the carrier loaded with the substrates between floors. Since a lifter penetrates a floor/ceiling structure of each floor, there is increased risk of a fire.

### SUMMARY

In order to solve one or more problems (e.g., the problems described above and/or other problems not explicitly described herein), the present disclosure provides a substrate transfer apparatus and a substrate transfer system with improved transport capability.

In order to solve one or more problems (e.g., the problems described above and/or other problems not explicitly described herein), the present disclosure provides a substrate transfer apparatus and a substrate transfer system capable of preventing the spread of fire.

In order to solve one or more problems (e.g., the problems described above and/or other problems not explicitly described herein), the present disclosure provides a substrate transfer system that includes a plurality of substrate transfer apparatuses separate from each other.

According to an aspect of the disclosure, a substrate transfer system includes: a first substrate transfer apparatus configured to transfer a wafer carrier; and a second substrate transfer apparatus below the first substrate transfer apparatus, the second substrate transfer apparatus configured to transfer the wafer carrier, in which the first substrate transfer apparatus includes: a first housing having a first opening and a second opening at a position different from the first opening in a first direction, and a first lifter configured to transfer the wafer carrier loaded into the first housing, and in which the second substrate transfer apparatus includes: a second housing having a third opening at a position that overlaps with the second opening in a second direction perpendicular to the first direction, and a fourth opening at a position different from the third opening in the first direction, and a second lifter configured to transfer the wafer carrier loaded into the second housing.

According to an aspect of the disclosure, a substrate transfer apparatus includes a housing including an first surface having an first opening thereon, and a second surface having a second opening thereon at a position spaced apart from the first opening in a first direction; and a lifter coupled to the first surface of the housing from an inside of the housing, in which the lifter is configured to: transfer a wafer carrier in the first direction or in a second direction perpendicular to the first direction, transfer out the wafer carrier, introduced through the first opening, through the second opening, or transfer in the wafer carrier through the second opening.

According to an aspect of the disclosure, a substrate transfer system includes a first substrate transfer apparatus configured to transfer a wafer carrier, the first substrate transfer apparatus comprising a first seating sensor configured to sense whether the wafer carrier is seated; a second substrate transfer apparatus below the first substrate transfer apparatus, the second substrate transfer apparatus configured to transfer the wafer carrier, the second substrate transfer apparatus comprising a second seating sensor configured to sense whether the wafer carrier is seated; a transfer device configured to transfer the wafer carrier into the first substrate transfer apparatus; and a controller configured to control at least one of the transfer device, the first substrate transfer apparatus, or the second substrate transfer apparatus based on output data of the first seating sensor or the second seating sensor, in which the first substrate transfer apparatus further includes: a first housing having a first opening and a second opening at a position different from the first opening in a first direction, and a first lifter configured to transfer the wafer carrier loaded into the first housing, and in which the second substrate transfer apparatus includes: a second housing having a third opening at a position that overlaps with the second opening in a second direction perpendicular to the first direction, and a fourth opening at a position different from the third opening in the first direction, and a second lifter configured to transfer the wafer carrier loaded into the second housing, and in which the controller is further configured to: determine whether the wafer carrier is seated based on the output data of the first seating sensor or the second seating sensor, in response to determining that the wafer carrier is not seated based on the output data sensed by the first seating sensor, control the transfer device to transfer the wafer carrier into the first housing, and in response to determining that the wafer carrier is not seated based on the output data sensed by the second seating sensor, control the first lifter to transfer the wafer carrier into the second housing.

According to an aspect of the disclosure, a substrate transfer system includes a first substrate transfer apparatus configured to transfer a wafer carrier, the first substrate transfer apparatus comprising a first seating sensor configured to sense whether the wafer carrier is seated; a second substrate transfer apparatus below the first substrate transfer apparatus, the second substrate transfer apparatus configured to transfer the wafer carrier, the second substrate transfer apparatus comprising a second seating sensor configured to sense whether the wafer carrier is seated; a transfer device configured to transfer the wafer carrier into the first substrate transfer apparatus; and a controller configured to control at least one of the transfer device, the first substrate transfer apparatus, or the second substrate transfer apparatus based on output data of the first seating sensor or the second seating sensor, in which the first substrate transfer apparatus further includes: a first housing having a first opening and a second opening at a position different from the first opening in a first direction, and a first lifter configured to transfer the wafer carrier loaded into the first housing, and in which the second substrate transfer apparatus includes: a second housing having a third opening at a position that overlaps with the second opening in a second direction perpendicular to the first direction, and a fourth opening at a position different from the third opening in the first direction, and a second lifter configured to transfer the wafer carrier loaded into the second housing, and in which the controller is further configured to: determine whether the wafer carrier is seated based on the output data of the first seating sensor or the second seating sensor, in response to determining that the wafer carrier is not seated based on the output data sensed by the first seating sensor, control the transfer device to transfer the wafer carrier into the first housing, and in response to determining that the wafer carrier is not seated based on the output data sensed by the second seating sensor, control the first lifter to transfer the wafer carrier into the second housing.

According to some embodiments of the present disclosure, a substrate transfer system with improved substrate transport capability can be provided, in which a plurality of substrate transfer apparatuses simultaneously move the transported objects between floors.

According to some embodiments, the substrate transfer apparatus and the substrate transfer system include a structure for blocking fire, and therefore, can prevent the spread of fire.

According to some embodiments, the substrate transfer system includes a plurality of substrate transfer apparatuses separate from each other, and therefore, can distribute the risk of system damage.

### BRIEF DESCRIPTION OF DRAWINGS

The above and other objects, features and advantages of the present disclosure will become more apparent to those of ordinary skill in the art by describing in detail exemplary embodiments thereof with reference to the accompanying drawings, in which:

FIG. 1 is a perspective view illustrating a substrate transfer system according to some embodiments;

FIG. 2 is a perspective view illustrating a substrate transfer apparatus according to some embodiments;

FIG. 3 is a cross-sectional view illustrating a substrate transfer apparatus according to some embodiments;

FIG. 4 is a diagram provided to explain some of components of a substrate transfer apparatus according to some embodiments;

FIG. 5 is a control block diagram of configurations for controlling a substrate transfer system according to some embodiments;

FIG. 6 is a flowchart provided to explain a method for transferring a wafer carrier by a substrate transfer apparatus according to some embodiments;

FIGS. 7 to 11 are diagrams provided to explain a process of transferring a wafer carrier by a substrate transfer apparatus according to some embodiments;

FIG. 12 is a flowchart provided to explain a process of transferring a wafer carrier by a substrate transfer system according to some embodiments;

FIGS. 13 to 15 are diagrams provided to explain a process of transferring a wafer carrier by a substrate transfer system according to some embodiments;

FIG. 16 is a flowchart provided to explain a process of transferring a wafer carrier by a substrate transfer system according to some embodiments; and

FIGS. 17 and 18 are diagrams provided to explain a process of transferring a wafer carrier by a substrate transfer system according to some embodiments.

### DETAILED DESCRIPTION

Hereinafter, a substrate transfer apparatus and a substrate transfer system according to some embodiments of the present disclosure will be described in detail with reference to the drawings.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

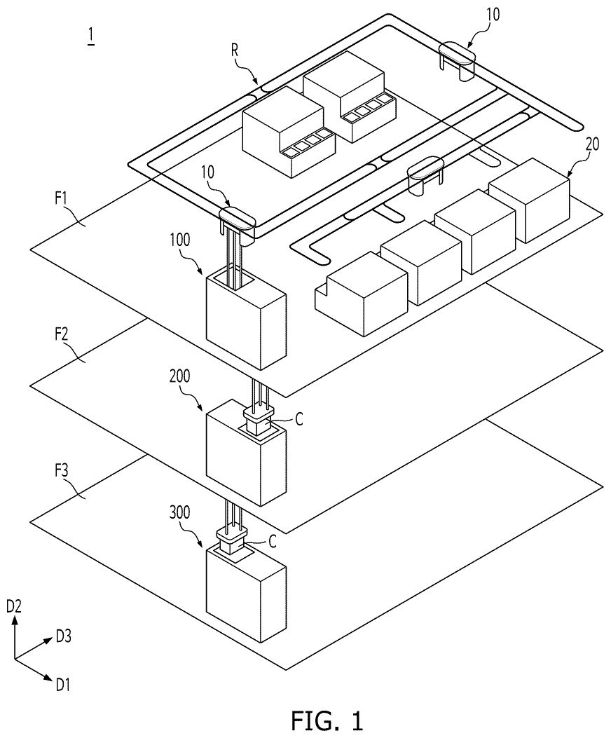

FIG. 1 is a perspective view illustrating a substrate transfer system according to some embodiments.

Referring to FIG. 1, a substrate transfer system 1 according to some embodiments may include a rail R, a transfer device 10, a substrate storage device 20, and substrate transfer apparatuses 100, 200, and 300. It is to be noted that in the drawing, only the rail R, the transfer device 10, and the substrate storage device 20 on a first floor F1 are illustrated as an example. However, as understood by one of ordinary skill in the art, other floors may have similar systems, or systems with different configurations.

A semiconductor fab may include the first floor F1, a second floor F2, and a third floor F3. The first floor F1 may be higher than the second floor F2. The second floor F2 may be higher than the third floor F3. For example, the first floor F1, the second floor F2, and the third floor F3 may be lower in that order. However, this is merely an example, and a semiconductor fab including more floors, or one floor divided into several floors may be implemented. Each floor of the semiconductor fab may have a bottom surface parallel to each of first and third directions D1 and D3. Further, each floor of the semiconductor fab may be disposed in a second direction D2 or a vertical direction. Although FIG. 1 illustrates floors F1-F3 arranged in a vertical direction (e.g., D2), as understood by one of ordinary skill in the art, one or more rooms may be parallel to each other at the same level in a horizontal direction (e.g., D1 or D3).

Each of the first floor F1, the second floor F2, and the third floor F3 may be formed with a passage for transferring a wafer carrier. The passages formed in each of the first floor F1, the second floor F2, and the third floor F3 may communicate with openings of the first to third substrate transfer apparatuses 100, 200 and 300. When two floors are arranged vertically, the passage may be through a floor/ceiling structure. When two rooms are on the same floor, the passage may be through a wall structure.

The substrate transfer system 1 may transfer a wafer carrier C. For example, the wafer carrier C may include a Front Opening Unified Pod (FOUP), a Front Opening Shipping Box (FOSB), a run box, etc.

The substrate transfer system 1 may be installed over several floors of the semiconductor fab. The substrate transfer system 1 may move the wafer between floors of the semiconductor fabs. For example, the substrate transfer system 1 may transfer the wafer carrier C from the first floor F1 to the second floor F2 or to the third floor F3.

The rail R may be fixed to a ceiling within the semiconductor fab. The rail R may be fixed to the ceiling of the semiconductor fab by a plurality of supporters. The rail R may be disposed above the substrate storage device 20. The rail R may be a path along which the transfer device 10 moves. For example, the rail R may include a straight section or a curved section. In one or more examples, the rail R may be installed on the bottom of a floor.

The transfer device 10 may be moved along the rail R. One or more transfer devices 10 may run on the rail R.

The transfer device 10 may include a transfer device body, a driving module, a hoist, and a gripper. The transfer device 10 may be, for example, an Overhead Hoist Transfer (OHT). The driving module may be coupled to the body to move the transfer device 10. One end of the hoist may be coupled to the body, and the other end of the hoist may be coupled to the gripper. The gripper may be lifted and lowered by the hoist. The gripper module may lift or lower the wafer carrier C.

In some embodiments, the transfer device 10 may further include a position sensor. The position sensor of the transfer device 10 may sense an alignment between the transfer device 10 and the port. For example, if the transfer device 10 is moved to above the substrate storage device 20, the position sensor may sense vertical alignment between the transfer device 10 and the target port. For another example, if the transfer device 10 is moved to a position above the substrate transfer apparatus, the position sensor may sense vertical alignment with respect to an upper opening of the substrate transfer apparatus.

The substrate storage device 20 may be disposed adjacent to the rail R. For example, the substrate storage device 20 may be disposed below the rail R. The substrate storage device 20 may include a plurality of storage spaces. The substrate storage device 20 may store the wafer carrier C. The wafer carrier C stored in the substrate storage device 20 may be moved to another substrate storage device 20 or to another floor of the semiconductor fab by the transfer device 10.

The substrate transfer apparatuses may include a first substrate transfer apparatus 100, a second substrate transfer apparatus 200, and a third substrate transfer apparatus 300. Each of the first substrate transfer apparatus 100, the second substrate transfer apparatus 200, and the third substrate transfer apparatus 300 may be installed on the first floor F1, the second floor F2, and the third floor F3, respectively.

Each of the first substrate transfer apparatus 100, the second substrate transfer apparatus 200, and the third substrate transfer apparatus 300 may be aligned in the second direction D2. Each of the first substrate transfer apparatus 100, the second substrate transfer apparatus 200, and the third substrate transfer apparatus 300 may be disposed vertically. Each of the first substrate transfer apparatus 100, the second substrate transfer apparatus 200, and the third substrate transfer apparatus 300 may transfer the wafer carrier C between floors.

The first substrate transfer apparatus 100 may receive the wafer carrier C transferred by the transfer device 10. In some embodiments, the first substrate transfer apparatus 100 may receive the wafer carrier C from the substrate transfer apparatus installed on the floor higher than the first floor F1.

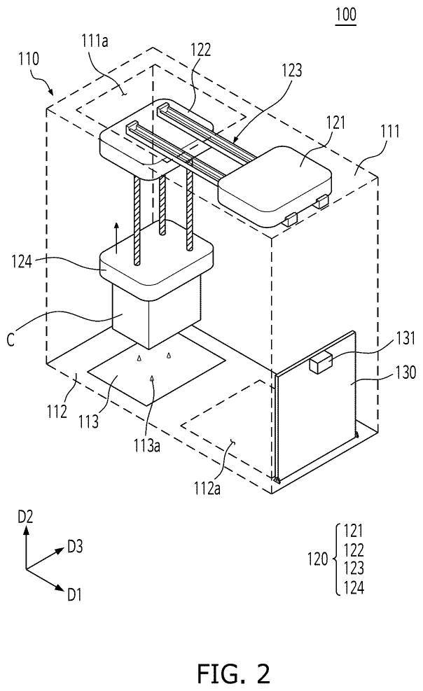

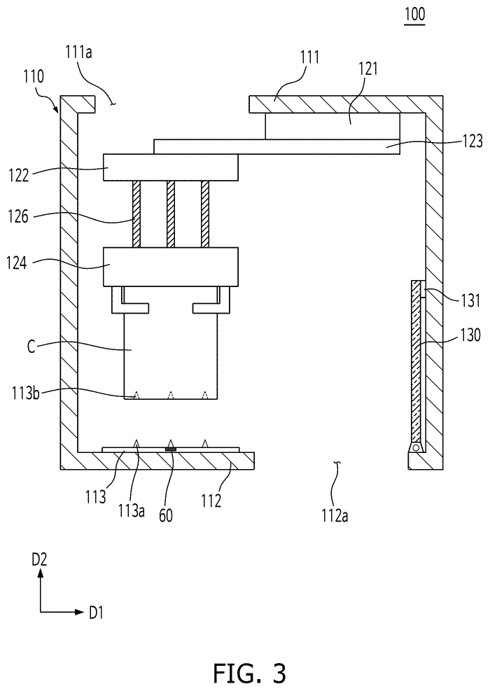

FIG. 2 is a perspective view illustrating the substrate transfer apparatus according to some embodiments. FIG. 3 is a cross-sectional view illustrating the substrate transfer apparatus according to some embodiments.

Referring to FIGS. 2 and 3, the substrate transfer apparatus 100 according to some embodiments may include a housing 110, a lifter 120, and a damper 130. The description of the substrate transfer apparatus 100 may be equally applicable to the first to third substrate transfer apparatuses described in FIG. 1. For example, the second substrate transfer apparatus may include a second housing, a second lifter, a second damper, etc. However, as understood by one or ordinary skill in the art, the embodiments are not limited to this configuration. For example, the structure of the substrate apparatus may vary between the floors.

The housing 110 may form an external appearance of the substrate transfer apparatus 100. The housing 110 may include an upper surface 111 and a lower surface 112. The upper surface 111 and the lower surface 112 may be parallel to each other, but embodiments are not limited thereto. For example, the housing 110 may have an approximately hexahedral shape. However, the shape of the housing 110 is not limited to these configurations, and the housing 110 may have any other shape as long as the upper surface 111 and the lower surface 112 are included.

An upper opening 111a may be formed on the upper surface 111, and a lower opening may be formed on the lower surface 112. The upper opening 111a and the lower opening 112a may be positioned to be offset from each other. Since the upper opening 111a is located on the upper surface 111 and the lower opening 112a is located on the lower surface, they may be spaced apart from each other in the second direction D2. Further, the upper opening 111a may be formed at different positions in the first direction D1 by being spaced apart from the lower opening 112a in the first direction D1 and. For example, the upper opening 111a and the lower opening 112a may have a substantially rectangular shape, but are not limited thereto. In some embodiments, the upper opening 111a may not overlap with the lower opening 112a in the second direction D2. In another embodiment, the upper opening 111a and the lower opening 112a may have portions overlapping with each other in the second direction D2.

The housing 110 may include a seating plate 113 for the wafer carrier C to seat on. The seating plate 113 may be disposed on the lower surface 112 of the housing 110. The seating plate 113 may be positioned to overlap with the upper opening 111a in the second direction D2. The wafer carrier C may be lowered in the second direction D2 through the upper opening 111a and may be seated on the seating plate 113. The seating plate 113 may be spaced apart from the lower opening 112a in the first direction D1. In some embodiments, the seating plate 113 may be a part of the lower surface 112 of the housing 110.

A position guide 113a may be formed in the seating plate 113. The position guide 113a may guide a seating position of the wafer carrier C. The position guide 113a may protrude upward from the seating plate 113. The position guide 113a may be inserted into a guide groove 113b formed on a lower surface of the wafer carrier C. The position guide 113a may have a shape corresponding to that of the guide groove 113b. For example, each of the position guide 113a and the guide groove 113b may have a conical shape. In one or more examples, the position guide 113a of the seating plate 113 may have a groove shape, and a protrusion for guidance may be formed on the lower surface of the wafer carrier C, but embodiments are not limited thereto.

A seating sensor 60 may be disposed on the seating plate 113. The seating sensor 60 may sense whether the wafer carrier C is seated on the seating plate 113. For example, the seating sensor 60 may include a pressure sensor, an optical sensor, etc. The seating sensor 60 may generate output data from a sensed signal. The generated output data may be transmitted to a controller.

The lifter 120 may be disposed inside the housing 110. The lifter 120 may be coupled to the upper surface 111 of the housing 110. The lifter 120 may be configured to transfer the wafer carrier C in the first direction D1 or the second direction D2. The lifter 120 may be configured to unload the wafer carrier C, loaded into the upper opening 111a, through the lower opening 112a. The lifter 120 may be configured to load the wafer carrier C through the lower opening 112a.

The lifter 120 may include a fixed plate 121, a movable plate 122, a driving device 123, and a gripper 124.

The fixed plate 121 may be coupled to the upper surface 111 of the housing 110. The fixed plate 121 may be coupled to the upper surface of the housing 110 from within the housing 110. The fixed plate 121 may be disposed so as not to overlap with the upper opening 111a in the second direction D2.

The movable plate 122 may be configured to be movable in the first direction D1. The movable plate 122 may be moved away from or closer to the fixed plate 121 in the first direction D1. The movable plate 122 may be moved to above the wafer carrier C to clamp the wafer carrier C located on the seating plate 113. Further, the movable plate 122 may lift and move the wafer carrier C to above the lower opening 112a to unload the same through the lower opening 112a.

The driving device 123 may move the movable plate 122 away from the fixed plate 121. The driving device 123 may generate a driving force for moving the movable plate 122. For example, the driving device 123 may include a motor, etc. The configuration and operation of the driving device 123 will be described below. Although, FIGS. 2 and 3 illustrate that the lifter 120 and driving device 123 are attached to the upper surface 111 of the housing 110, the embodiments are not limited to these configurations. For example, the lifter 120 and the driving device 123 may be attached to a side surface or side wall of the housing 110. Furthermore, when the lifter 120 and the driving device are attached the side surface or side wall of the housing 110, the openings 111a and 112a may be aligned with each other.

The gripper 124 may clamp the wafer carrier C. The gripper 124 may include a gripping part for gripping the wafer carrier C. The gripping part may grip the wafer carrier C. The gripper 124 may be connected to the movable plate 122. For example, the movable plate 122 and the gripper 124 may be connected to each other through a cable 126. The gripper 124 may be moved away from or closer to the movable plate 122 in the second direction D2.

The damper 130 may open or close the lower opening 112a. The damper 130 may be rotatably coupled to the lower surface 112 of the housing 110. A fixed end of the damper 130 may be rotatably coupled to one side of the lower opening 112a. For example, the fixed end of the damper 130 may be hinged to the one side of the lower opening 112a.

The damper 130 may be maintained in a state of opening the lower opening 112a for the transfer of the wafer carrier C. The damper 130 may close the lower opening 112a, if an event such as fire or power failure occurs in the floor where the substrate transfer apparatus is installed or in another floor of the semiconductor fab.

In some embodiments, the damper 130 may include a magnetic metal material. For example, the damper 130 may include iron (Fe), nickel (Ni), cobalt (Co), etc. The damper 130 may have a predetermined thickness. For example, the damper 130 may have a thickness of about 2 mm.

A damper holder 131 may hold the damper 130 such that the damper 130 remains in the state of opening the lower opening 112a. For example, the damper 130 may be positioned perpendicular to the lower surface 112 of the housing 110. In one or more examples, the damper 130 may be positioned in an inclined state, forming an acute angle with the lower surface 112 of the housing 110. In some embodiments, the damper 130 may be configured such that if the damper holder 131 is released from its fixed state due to occurrence of an event, etc., the damper 130 may be moved in the direction of closing the lower opening 112a by its own weight.

The damper holder 131 may be disposed on a side surface of the housing 110. The damper holder 131 may fix a free end of the damper 130. For example, while the damper 130 is opening the lower opening 112a, the damper holder 131 may be disposed at a position corresponding to the free end of the damper 130. For example, the damper holder 131 may include an electromagnet that holds the damper 130 in place when in a fixed state, and releases the damper 130 when in a state of closing the lower opening 112a. In one or more examples, the damper holder 131 may be configured to switch magnetic polarities. For example, the damper holder 131 may be an opposite polarity of the damper 130 that causes the damper 130 to move from a closed state to an open state in which the damper 130 is fixed to the damper holder 131. In one or more examples, the damper holder 131 may change a magnetic polarity to be the same as the magnetic polarity of the damper 130 such that the damper 130 is repelled from the damper holder 131 to close the lower opening 112a. In some embodiments, the damper holder 131 may fix the damper 130 with a mechanical method such as interference, friction, etc. For example, the damper holder 131 may include a latch, a hook, etc.

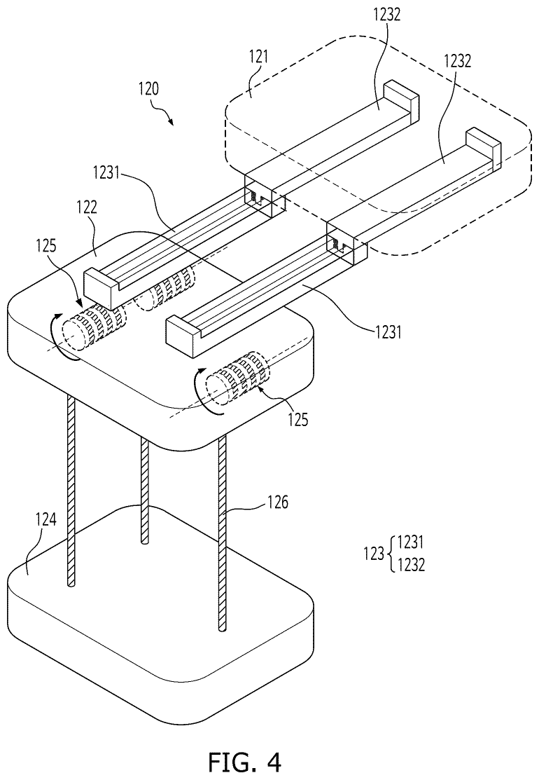

FIG. 4 is a diagram provided to explain some of components of the substrate transfer apparatus according to some embodiments.

Referring to FIG. 4, the lifter 120 may further include the driving device 123, a drum 125, and a cable 126.

The driving device 123 may be coupled to each of the movable plate 122 and the fixed plate 121. The driving device 123 may move the movable plate 122 with respect to the fixed plate 121. For example, the driving device 123 may include a linear motor (LM) guide.

The driving device 123 may include a first guide rail 1231, a second guide rail 1232, and a driving unit.

The first guide rail 1231 may be coupled to an upper surface of the movable plate 122. The first guide rail 1231 may extend along the first direction D1. The first guide rail 1231 may be configured as a pair. A groove extending along the first direction D1 may be formed in the first guide rail 1231.

The second guide rail 1232 may be coupled to a lower surface of the fixed plate 121. In some embodiments, the first guide rail 1231 may be coupled to the fixed plate 121, and the second guide rail 1232 may be coupled to the movable plate 122.

The second guide rail 1232 may be provided to be movable along the groove formed in the first guide rail 1231. The groove formed in the first guide rail 1231 and a moving block may have a shape corresponding to each other. For example, the second guide rail 1232 may include a protrusion to be inserted into the groove formed in the first guide rail 1231. In this way, the second guide rail 1232 may be engaged with the first guide rail 1231. In some embodiments, the male-female structure of the first guide rail 1231 and the second guide rail 1232 may be reversed. For example, the first guide rail 1231 may include a protrusion, and the second guide rail 1232 may include a groove.

The first guide rail 1231 and the second guide rail 1232 may overlap with each other in the first direction D1. The sum of the length of the first guide rail 1231 and the length of the second guide rail 1232 may be selectively increased or decreased. The lengths of the first guide rail 1231 and the second guide rail 1232 may increase in the first direction D1 as there are fewer overlapping portions, and may decrease in the first direction D1 as there are more overlapping portions.

The driving unit may be a linear motor including a roller screw or a ball bearing. The driving unit may convert a rotational motion into a linear motion. For example, the driving unit may convert the rotary force of the motor into a linear motion to move the movable plate 122 in the extension direction of the first guide rail 1231 (e.g., in the first direction D1).

At least one of the first guide rail 1131 and the second guide rail 1132 may be provided with the driving unit. By the driving force generated by the driving unit, the first guide rail 1231 and the second guide rail 1232 may be moved relative to each other. For example, if the second guide rail 1232 is coupled to the fixed plate 121, the first guide rail 1231 may be moved even if the driving force occurs in the second guide rail 1232. If the driving force is generated in the first guide rail 1231, the first guide rail 1231 and the movable plate 122 may be moved.

In some embodiments, a ball bearing may be disposed between the first guide rail 1231 and the second guide rail 1232. The ball bearing may reduce friction between the first guide rail 1231 and the second guide rail 1232 to ensure smooth relative movement of the first guide rail 1231 and the second guide rail 1232.

The drum 125 may be disposed on the movable plate 122. For example, the drum 125 may be disposed within the movable plate 122. The cable 126 may be wound around an outer circumferential surface of the drum 125. One end of the cable 126 may be coupled to the drum 125, and the other end of the cable 126 may be coupled to the gripper 124. Specifically, the one end of the cable 126 may be coupled to the outer circumferential surface of the drum 125, and the other end of the cable 126 may be coupled to an upper surface of the gripper 124.

The drum 125 may be rotated in an axial direction. For example, the drum 125 may include a driving motor. The cable 126 may be wound around the outer circumferential surface of the drum 125 as the drum 125 is rotated in one direction. The cable 126 around the outer circumferential surface of the drum 125 may be unwound as the drum 125 is rotated in the opposite direction. As described above, the vertical length of the cable 126 may increase or decrease by the rotation of the drum 125. For example, by the rotation of the drum 125, the gripper 124 coupled to the other end of the cable 126 may be moved in the vertical direction (in the second direction D2).

If the cable 126 is fully wound around the drum 125, the upper surface of the gripper 124 may be in contact with a lower surface of the movable plate 122. The gripper 124 and the movable plate 122 may be moved integrally.

A plurality of drums 125 and cables 126 may be provided. For example, at least three drums 125 and cables 126 may be provided to allow the gripper 124 to be suspended stably. Positions of the drum 125 and the cable 126 may be determined in consideration of the center of gravity of the gripper 124 and the wafer carrier C.

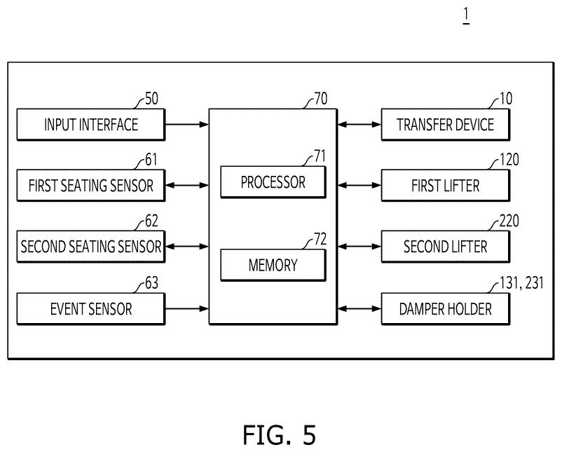

FIG. 5 is a control block diagram of configurations for controlling the substrate transfer system.

Referring to FIG. 5, the substrate transfer system 1 according to some embodiments may include an input interface 50, a first seating sensor 61, a second seating sensor 62, an event sensor 63, a controller 70, a transfer device 10, a first lifter 120, a second lifter 220, and damper holders 131 and 231.

The input interface 50 may receive a control command from a user. For example, the input interface 50 may receive a command for controlling the components of the substrate transfer system 1. For example, a target floor to transfer the wafer carrier to may be set through the input interface 50. The control command input through the input interface 50 may be transmitted to the controller 70. The controller 70 may control the transfer device 10, the first lifter 120, the second lifter 220, and the damper holders 131 and 231 based on the input control command.

The first seating sensor 61 may sense whether the wafer carrier is seated on the seating plate of the first substrate transfer apparatus. The second seating sensor 62 may sense whether the wafer carrier is seated on the seating plate of the second substrate transfer apparatus. The first seating sensor 61 and the second seating sensor 62 may generate output data from the sensed signal. The generated output data may be transmitted to the controller 70. The controller 70 may generate the output data from the sensed signal of the first seating sensor 61 and the second seating sensor 62 and control the transfer device 10, the first lifter 120, the second lifter 220, and the damper holders 131 and 231 based on the output data. In one or more examples, the first seating sensor 61 and the second seating sensor 62 may be infrared sensors, where an infrared signal being block or reduced to below a threshold value indicates that a wafer is seated.

The controller 70 may determine whether the wafer carrier C is seated or not based on the output data of the first seating sensor 61 or the second seating sensor 62. The controller 70 may control the transfer device 10 or the first lifter 120 based on the determination as to whether wafer carrier C is seated or not. For example, if it is determined that the wafer carrier C is not seated on the first substrate transfer apparatus based on the output data sensed by the first seating sensor 61, the controller 70 may control so that the transfer device 10 is operated.

The event sensor 63 may sense whether an event occurs inside the semiconductor fab. For example, the event sensor 63 may sense an event such as fire or power failure inside the semiconductor fab. The event sensor 63 may be disposed in each floor of the semiconductor fab. The event sensor 63 may sense whether an event occurs in each floor. For example, the event sensor 63 disposed on the second floor may sense if a fire or a power failure occurs in the second floor. The event sensor 63 may generate output data from the sensed signal, and the generated output data may be transmitted to the controller 70. The controller 70 may control the first damper holder 131 so that the first damper closes the first lower opening based on the output data generated from the event sensor 63. In one or more examples, the controller 70 may control the second damper holder 231 so that the second damper closes the second lower opening based on the output data generated from the event sensor 63. In some embodiments, the controller 70 may directly control the first damper or the second damper.

The controller 70 may control at least one of the transfer device 10, the first lifter 120, the second lifter 220, and the damper holders 131 and 231 based on at least one of input data received from the input interface 50, output data received from the first seating sensor 61 and the second seating sensor 62, and output data received from the event sensor 63.

If the controller 70 controls the components of the substrate transfer apparatus, this control may include all of directly transmitting a control signal to the components, transmitting a control signal to a separate driving device that drives the components, and transmitting a control signal to another component in the middle that is required to control the component. In one or more examples, the controller 70 may be central controller that communicates and controls each of the substrate transfer apparatuses 100, 200, and 300 (FIG. 1). For example, each of the substrate transfer apparatuses 100, 200, and 300 may have a respective controller that communicates with and receives instructions from the controller 70.

The controller 70 may include a memory 72 that stores a program and various types of data for executing the operations described above or described below, and a processor 71 that processes data by executing the program stored in the memory 72.

The memory 72 may include at least one of a volatile memory such as a static random access memory (SRAM), and a dynamic random access memory (DRAM), and a non-volatile memory such as a flash memory, a read only memory (ROM), an erasable programmable read only memory (EPROM), and an electrically erasable programmable read only memory (EPROM).

The non-volatile memory may operate as an auxiliary memory device of the volatile memory, and may retain stored data even if the power of the substrate transfer apparatus is cut off. For example, the non-volatile memory may store a control program and control data for controlling the operation of the substrate transfer apparatus.

Unlike the non-volatile memory, the volatile memory may lose stored data if power of the substrate transfer apparatus is cut off. The volatile memory may load a control program and control data from the non-volatile memory and temporarily store the control program and control data, temporarily store an input setting value or control command, or temporarily store a control signal, etc. output from the processor 71.

The processor 71 may process data or output a control signal according to the program stored in the memory 72. For example, the processor 71 may process data or output a control signal according to a program stored in the memory 72 that includes instructions for executing an operation of the substrate transfer apparatus or the substrate processing method.

The processor 71 and the memory 72 may be provided in a single configuration or may be provided in a plurality of configurations according to their capacities. In addition, the processor 71 and the memory 72 may be provided as physically separated components or may be provided as a single chip.

Hereinafter, a method for controlling the components of the substrate transfer system, executed by the controller 70 or the processor 71, will be described in detail.

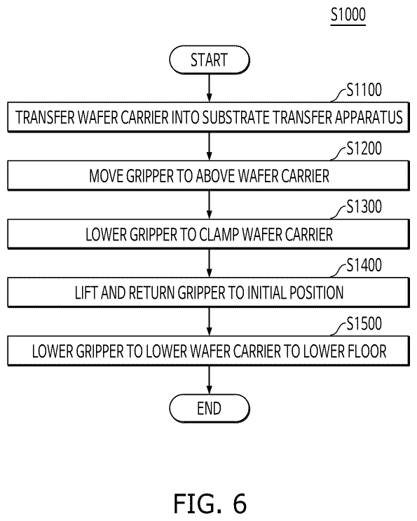

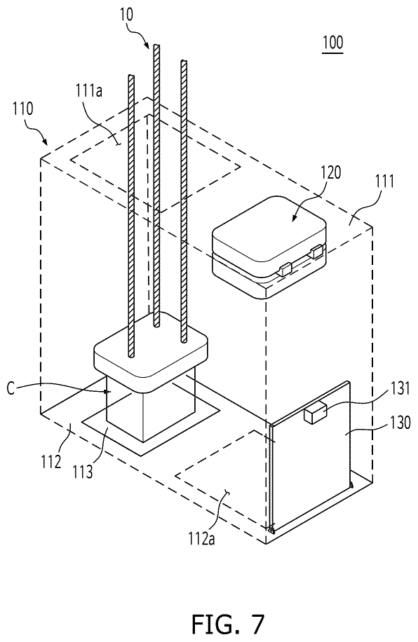

FIG. 6 is a flowchart provided to explain a process of transferring the wafer carrier by the substrate transfer apparatus according to some embodiments. FIGS. 7 to 11 are diagrams provided to explain a process of transferring the wafer carrier by the substrate transfer system according to some embodiments.

Referring to FIGS. 6 to 11, the process of transferring the wafer carrier C from an upper floor to a lower floor by the substrate transfer apparatus 100 will be described. The process of transferring the wafer carrier C from the lower floor to the upper floor by the substrate transfer apparatus 100 may be performed in the reverse order of the flowchart illustrated in FIG. 6.

Referring to FIGS. 6 and 7, the substrate transfer method S1000 according to some embodiments may include loading (S1100) the wafer carrier C into the substrate transfer apparatus 100.

The wafer carrier C may be loaded through the upper opening 111a of the housing 110. For example, the wafer carrier C may be loaded by the transfer device 10 or the substrate transfer apparatus of the upper floor. The wafer carrier C may be loaded in the vertical direction (in the second direction D2). The wafer carrier C loaded into the substrate transfer apparatus 100 may be seated on the seating plate 113. In this process, the wafer carrier C may be seated in position by the position guide 113a formed on the seating plate 113.

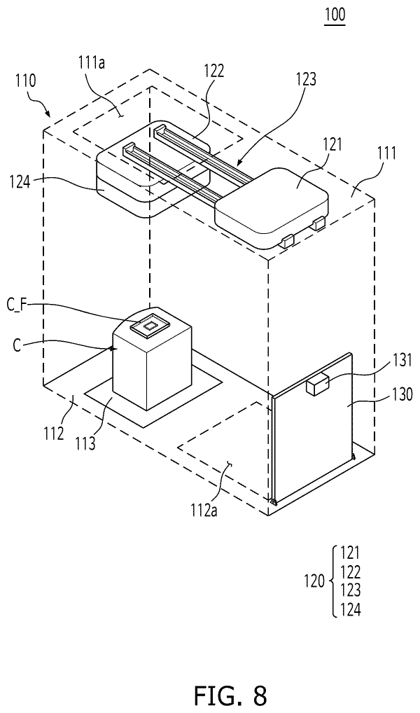

Referring to FIGS. 6 and 8, the substrate transfer method S1000 according to some embodiments may include the gripper being moved (S1200) to above the wafer carrier.

Before the wafer carrier C is transferred into the substrate transfer apparatus, the gripper 124 may be in alignment with the fixed plate 121 and the movable plate 122 in the vertical direction (in the second direction D2). The gripper 124 in vertical alignment with the fixed plate 121 and the movable plate 122 may be referred to as being in an initial position.

The wafer carrier C may be loaded into the substrate transfer apparatus by the transfer device, and the wafer carrier C may be seated on the seating plate 113. In order to transfer the wafer carrier C to the next floor (e.g., to the lower floor), the gripper 124 may be moved to above the wafer carrier C. The movable plate 122 and the gripper 124 may be moved in a horizontal direction (e.g., in the first direction D1) away from the fixed plate 121.

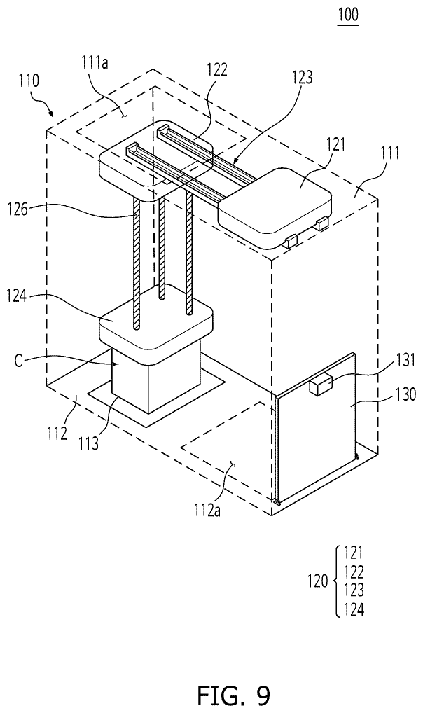

Referring to FIGS. 6 and 9, the substrate transfer method S1000 according to some embodiments may include the gripper being lowered to clamp (S1300) the wafer carrier.

The drum 125 may be rotated in the direction of unwinding the cable 126 from the outer circumferential surface of the drum 125. As the cable 126 is unwound, the vertical length of the cable 126 may be increased. For example, the gripper 124 connected to the other end of the cable 126 may be lowered in the vertical direction (in the second direction D2). If the gripper 124 is lowered to a height where the gripper 124 can clamp the wafer carrier C, the rotation of the drum 125 may be stopped. The gripping part of the gripper 124 may be operated to clamp the wafer carrier C. For example, the gripping part may clamp a flange portion C_F of the wafer carrier C.

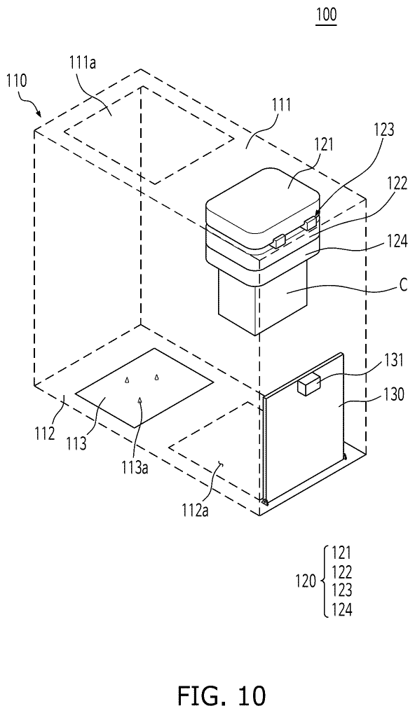

Referring to FIGS. 6 and 10, the substrate transfer method S1000 according to some embodiments may include the gripper 124 being lifted and returned (S1400) to the initial position.

The gripper 124 may transfer the wafer carrier C in the second direction D2 within the first housing 110. The drum 125 may be rotated in the direction of winding the cable 126 around the outer circumferential surface of the drum 125. As the cable 126 is wound, the vertical length of the cable 126 may be reduced. For example, the gripper 124 connected to the other end of the cable 126 may be lifted in the vertical direction (e.g., in the second direction D2). The gripper 124 may be lifted while clamping the wafer carrier C. If the gripper 124 is lifted to the same height as the initial position of the gripper 124, the rotation of the drum 125 can be stopped. For example, the gripper 124 may be lifted until the upper surface of the gripper 124 contacts the lower surface of the movable plate 122. As such, the gripper 124 may be lifted while clamping the wafer carrier C and reach the same height as the initial position.

The gripper 124 may be moved to the initial position. The gripper 124 may transfer the wafer carrier C in the first direction D1 within the first housing 110. The gripper 124 may be moved in the horizontal direction (e.g., in the first direction D1). The movable plate 122 and the gripper 124 may be moved in the horizontal direction (e.g., in the first direction D1) toward the fixed plate 121. The movable plate 122 and the gripper 124 may be moved to a point of alignment with the fixed plate 121 in the vertical direction (e.g., in the second direction D2). The gripper 124 may return to the initial position while clamping the wafer carrier C.

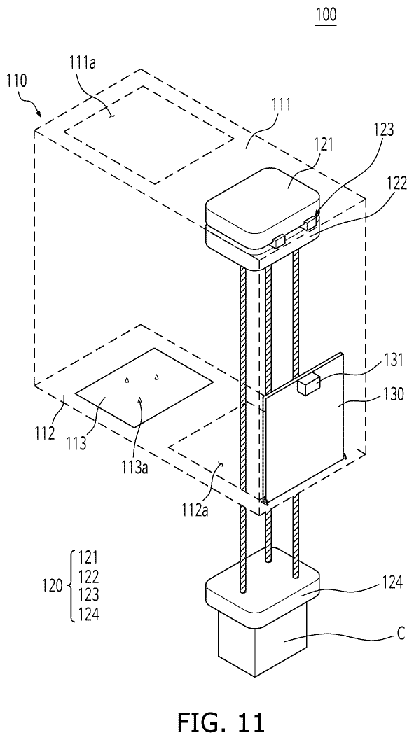

Referring to FIGS. 6 and 11, the substrate transfer method (S1000) according to some embodiments may include the gripper 124 being lowered to lower (S1500) the wafer carrier C to the lower floor.

At a position where the first lower opening 112a overlaps with the second upper opening formed in the second substrate transfer apparatus of the lower floor in the second direction D2, the gripper 124 may transfer the wafer carrier C in the second direction D2 through the first lower opening 112a and the second upper opening. The gripper 124 at an initial position may be in alignment with the lower opening 112a in the vertical direction (in the second direction D2). Since the gripper 124 is in the state of clamping the wafer carrier C, as the gripper 124 is lowered, the wafer carrier C may be transferred to the lower floor through the lower opening 112a. In order for the gripper 124 to be lowered, the drum 125 may be rotated in the direction of unwinding the cable 126. The drum 125 may be rotated in the direction of unwinding the cable 126, increasing the vertical length of the cable 126. For example, the gripper 124 connected to the other end of the cable 126 may be lowered in the vertical direction (e.g., in the second direction D2). As such, the gripper 124 and the wafer carrier C may be transferred to the substrate transfer apparatus of the lower floor through the lower opening.

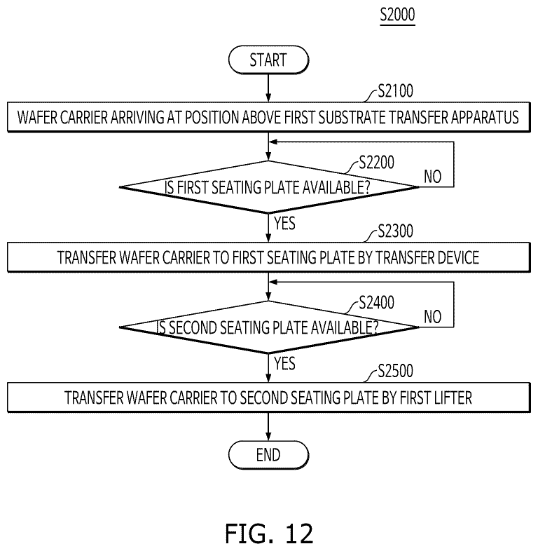

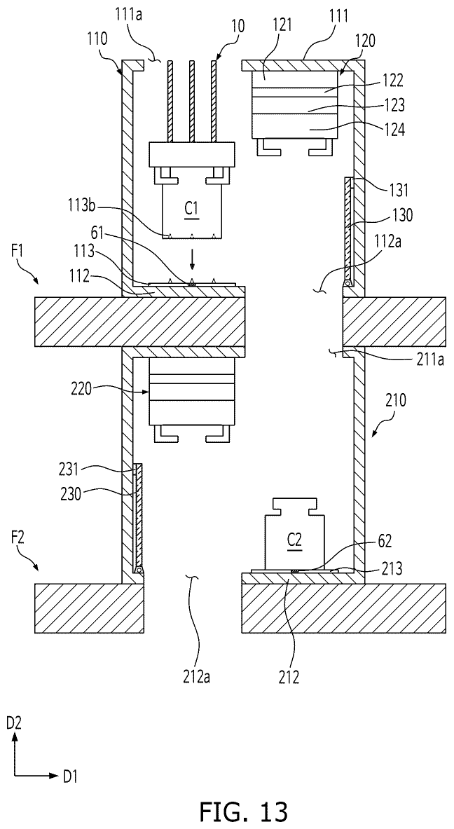

FIG. 12 is a flowchart provided to explain a process of transferring the wafer carrier by the substrate transfer system according to some embodiments. FIGS. 13 to 15 are diagrams provided to explain a process of transferring the wafer carrier by the substrate transfer system according to some embodiments.

Referring to FIGS. 12 to 15, the process of transferring the wafer carrier C between floors by the substrate transfer system according to some embodiments will be described. For example, a process of loading the wafer carrier into the first substrate transfer apparatus installed in the first floor F1 and transferring the wafer carrier to the lower floor through the second substrate transfer apparatus installed in the second floor F2.

Referring to FIGS. 12 to 15, a substrate transfer method S2000 according to some embodiments may include the wafer carrier arriving S2100 at a position above the first substrate transfer apparatus.

The transfer device 10 may be moved to above the first substrate transfer apparatus to transfer the first wafer carrier C1 to the first substrate transfer apparatus. For example, the transfer device 10 may arrive at a position that overlaps with the first upper opening 111a in the second direction D2. In some embodiments, this may refer to a position where the wafer carrier is spaced apart from the correct position on the first seating plate in the second direction D2.

The substrate transfer method S2000 according to some embodiments may include determining S2200 whether the first seating plate is available.

The first seating sensor 61 may sense whether the first seating plate 113 is available. The first seating sensor 61 may sense whether the wafer carrier is seated on the first seating plate 113 and generate output data accordingly. The first seating sensor 61 may transmit the generated output data to the controller.

If it is determined that the wafer carrier is not seated on the first seating plate 113 based on the output data generated by the first seating sensor, the controller may control so that the transfer device 10 is operated. If it is determined that the wafer carrier is seated on the first seating plate 113 based on the output data generated by the first seating sensor, the controller may control so that the transfer device 10 is not operated. In other words, if it is determined that the first seating plate 113 is available based on the output data generated by the first seating sensor 61, the controller may control so that the transfer device 10 is operated. If it is determined that the first seating plate 113 is not available based on the output data generated by the first seating sensor 61, the controller may control so that the transfer device 10 is not operated. In this case, the transfer device 10 may stand by above the first substrate transfer apparatus or may be moved to another substrate transfer apparatus.

The substrate transfer method S2000 according to some embodiments may include the transfer device transferring S2300 the wafer carrier to the first seating plate.

If it is determined that the wafer carrier is not seated on the first seating plate 113 based on the output data generated by the first seating sensor 61, the controller may load the first wafer carrier C1 into the first housing 110. The transfer device 10 may transfer the first wafer carrier C1 to the first seating plate 113. The first wafer carrier C1 may be lowered to a position where the position guide 113a formed on the first seating plate 113 may be inserted into the guide groove 113b. In some embodiments, the first wafer carrier C1 may be transferred from a substrate transfer apparatus positioned above the first floor F1 into the first substrate transfer apparatus.

The substrate transfer method S2000 according to some embodiments may include determining S2400 whether the second seating plate is available.

The second seating sensor 62 may sense whether the second seating plate 213 is available. The second seating sensor 62 may sense whether the wafer carrier is seated on the second seating plate 213 and generate output data. The second seating sensor 62 may transmit the generated output data to the controller.

If it is determined that the wafer carrier is not seated on the second seating plate 213 based on the output data generated by the second seating sensor 62, the controller may control so that the first lifter 120 is operated. If it is determined that the wafer carrier is seated on the second seating plate 213 based on the output data generated by the second seating sensor 62, the controller may control so that the first lifter 120 is not operated. In other words, if it is determined that the second seating plate 213 is available based on the output data generated by the second seating sensor 62, the controller may control so that the first lifter 120 is operated. If it is determined that the second seating plate 213 is not available based on the output data generated by the second seating sensor 62, the controller may control so that the first lifter 120 is not operated.

The substrate transfer method S2000 according to some embodiments may include the first lifter transferring S2500 the wafer carrier to the second seating plate.

The controller may determine that the wafer carrier is not seated on the second seating plate 213 and control the operation of the first lifter 120. The controller may control the first lifter 120 to transfer the first wafer carrier C1 to the second substrate transfer apparatus.

Referring to FIG. 13, inside the second substrate transfer apparatus installed in the second floor F2, the second wafer carrier C2 may be in the seated state. For example, the second seating sensor 62 may sense that the wafer carrier is seated on the second seating plate 213. Since the second seating plate 213 is not available, the controller may keep the first lifter 120 in the standby mode so that the first lifter is not operated.

In some embodiments, if the wafer carrier is not in the state of being seated on the second seating plate 213, the second seating sensor 62 may sense that the second seating plate 213 is in the available state and transmit the corresponding output data to the controller. Since the second seating plate is available, the controller may control the first lifter 120 to transfer the first wafer carrier C1 to the second seating plate 213.

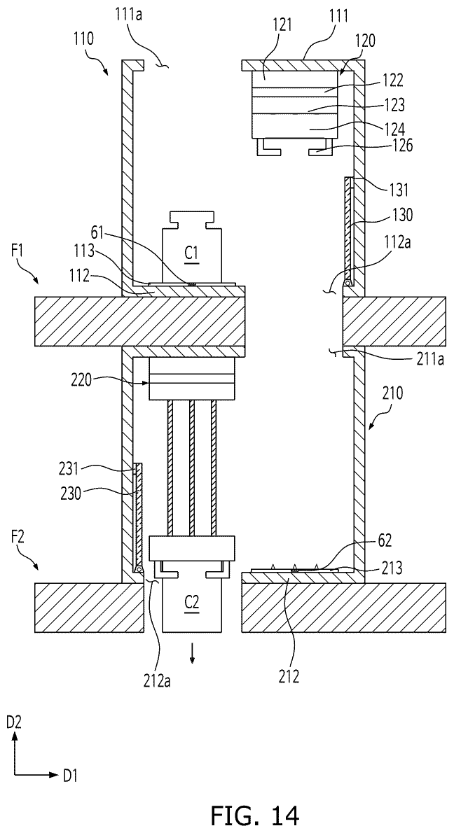

Referring to FIG. 14, the second lifter 220 may transfer the second wafer carrier C2 to the lower floor. For example, the controller may control the second lifter 220 to transfer the second wafer carrier C2 to the lower floor based on the state of the substrate transfer apparatus located on the lower floor. The second lifter 220 may transfer the second wafer carrier C2 through the second lower opening 212a. If the second lifter 220 lifts the second wafer carrier C2 from the second seating plate 213, the second seating sensor 62 may sense that the second seating plate 213 is in the available state. The second seating sensor 62 may sense whether the second seating plate 213 is available and transmit generated output data to the controller.

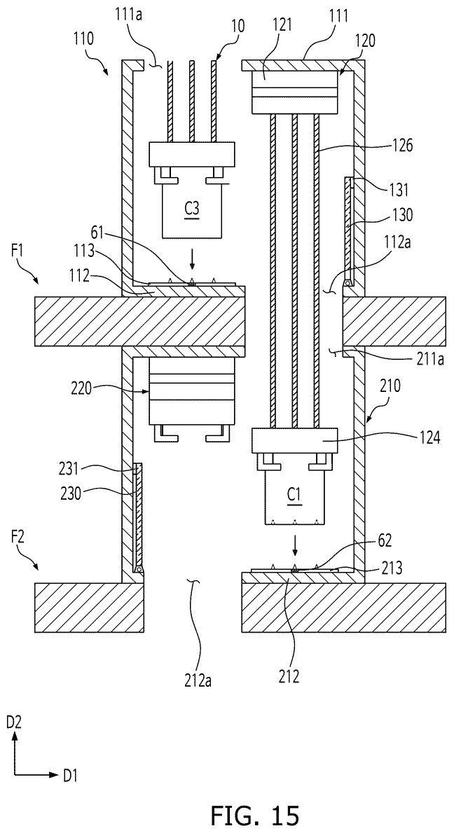

Referring to FIG. 15, the first lifter 120 may load the first wafer carrier C1 into the second housing 210. At a position where the first lower opening 112a and the second upper opening overlap with each other in the second direction D2, the gripper 124 may transfer the wafer carrier C in the second direction D2 through the first lower opening 112a and the second upper opening. The first wafer carrier C1 may be transferred onto the second seating plate 213. The first wafer carrier C1 may be lowered to a position where the position guide 213a formed on the second seating plate 213 may be inserted into the guide groove 113b.

While the first lifter 120 is transferring the first wafer carrier C1, the transfer device 10 may load a third wafer carrier C3 into the first housing 110. For example, the first lifter 120 and the transfer device 10 may be simultaneously operated. In some embodiments, while the second lifter 220 is transferring a wafer carrier to the third floor, at least one of the first lifter 120 or the transfer device 10 may transfer another wafer carrier. As such, the substrate transfer system according to some embodiments may improve the transfer capability because each substrate transfer apparatus may transfer the wafer carrier at the same time.

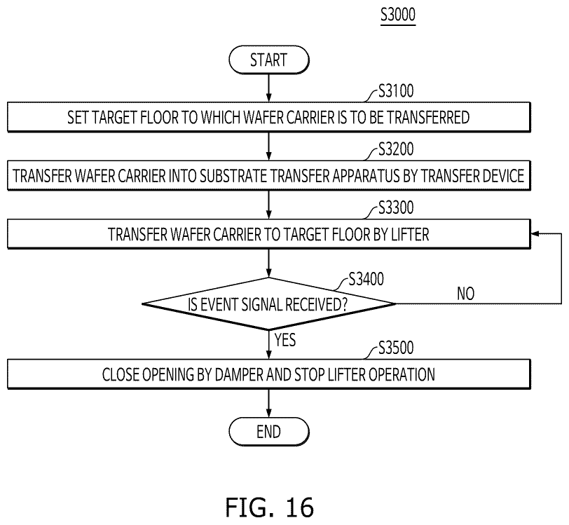

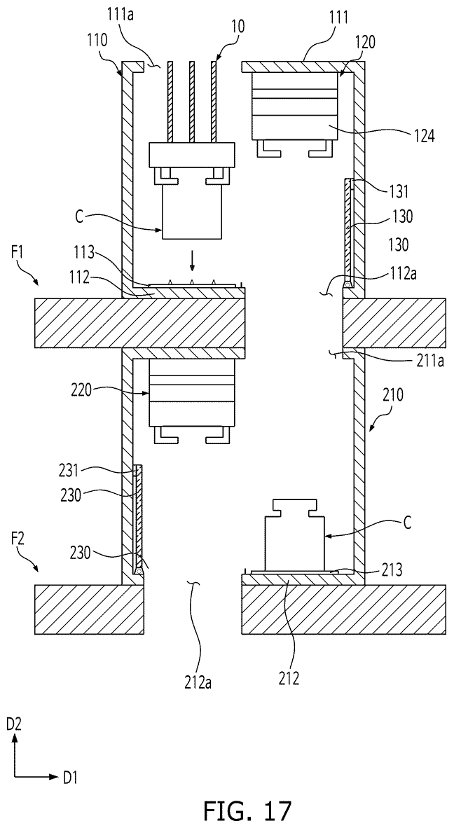

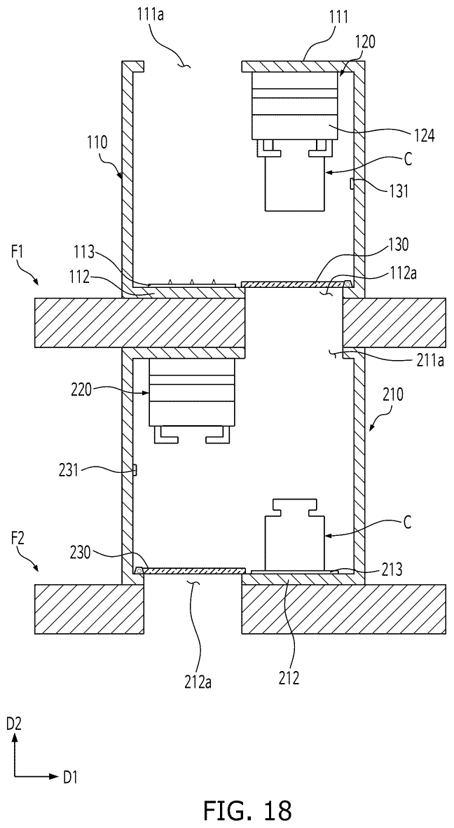

FIG. 16 is a flowchart provided to explain a process of transferring the wafer carrier by the substrate transfer system according to some embodiments. FIGS. 17 and 18 are diagrams provided to explain a process of transferring the wafer carrier by the substrate transfer system according to some embodiments.

Referring to FIGS. 16 and 17, a substrate transfer method S3000 according to some embodiments may include setting S3100 a target floor to which the wafer carrier is to be transferred.

The target floor to which the wafer carrier is to be transferred may be previously stored in the memory of the controller. The target floor to which the wafer carrier is to be transferred may be input by a user or other software. For example, the user may enter a control command through the input interface, instructing to carry the wafer carrier to the second floor.

The substrate transfer method S3000 according to some embodiments may include the transfer device transferring S3200 the wafer carrier into the substrate transfer apparatus.

The transfer device 10 may load the wafer carrier C into the first housing 110. The transfer device 10 may load the wafer carrier C into the first substrate transfer apparatus through the first upper surface opening 111a. Specifically, the transfer device 10 may transfer the wafer carrier C so that the wafer carrier C is seated on the first seating plate 113.

The substrate transfer method S3000 according to some embodiments may include the lifter transferring S3300 the wafer carrier to the target floor.

The first lifter 120 may transfer the wafer carrier C to the second substrate transfer apparatus. For example, the controller may cause the gripper 124 to be lowered to lift the wafer carrier C seated on the first seating plate 113 in the second direction D2 and then move the same in the first direction D1. The wafer carrier C may be moved to a position that overlaps with the first lower opening 112a and the second upper opening 211a in the second direction D2.

The first damper 130 may be held in a state of opening the first lower opening 112a by the first damper holder 131. The second damper 230 may be held in a state of opening the second lower opening 212a by the second damper holder 231.

The substrate transfer method S3000 according to some embodiments may include determining S3400 the event signal is received. For example, while the first lifter 120 is transferring the wafer carrier C, an event signal may occur on the second floor F2. The event sensor disposed on the second floor F2 may sense the event signal. For example, the event signal may be sensed when a fire or power failure occurs in the semiconductor fab. The event sensor 63 may sense the event signal and transmit the event signal to the controller.

The substrate transfer method S3000 according to some embodiments may include controlling S3500 the damper to close the opening and stop the lifter operation. In some embodiments, the controller may control the first damper 130 or the second damper 230 to close the first lower opening 112a or the second lower opening 212a based on the event signal sensed by the event sensor. In some embodiments, each of the first damper 130 and the second damper 230 may be configured to be rotated by a driving force generated by a motor. For example, a motor may be embedded in the hinge coupled to each of the first damper 130 and the second damper 230. The motor may generate a driving force to rotate the first damper 130 and the second damper 230. By controlling the motor, the controller may control the first damper 130 and the second damper 230 to close the first lower opening 112a and the second lower opening 212a.

In some embodiments, based on the event signal, the controller may control the first damper holder 131 to release the first damper 130 from the state of opening the first lower opening 112a. Based on the event signal, the controller may control the second damper holder 231 to release the second damper 230 from the state of opening the second lower opening 212a. For example, the first damper holder 131 and the second damper holder 231 may be electromagnets. The controller may block the supply of current to each of the first damper holder 131 and the second damper holder 231. Since the current is not supplied to the first damper holder 131 and the second damper holder 231, they may not generate magnetic force and may not be able to fix the first damper 130 and the second damper 230.

In some embodiments, the first damper 130 and the second damper 230 may be in a state of being elastically biased to the direction of closing the first lower opening 112a and the second lower opening 212a. The first damper holder 131 and the second damper holder 231 may generate attractive force in a direction opposite to the force that acts in the direction in which the first damper 130 and the second damper 230 close the first lower opening 112a and the second lower opening 212a.

Although the present disclosure has been described above by way of certain embodiments and drawings, the present disclosure is not limited thereto, and it goes without saying that various changes and modifications can be made within the equivalent scope of the technical idea of the present disclosure and the claims to be described below by those of ordinary skill in the art.

What is claimed is:

1. A substrate transfer system, comprising:
a first substrate transfer apparatus configured to transfer a wafer carrier; and
a second substrate transfer apparatus below the first substrate transfer apparatus, the second substrate transfer apparatus configured to transfer the wafer carrier,
wherein the first substrate transfer apparatus comprises:
a first housing having a first opening and a second opening at a position different from the first opening in a first direction, and
a first lifter configured to transfer the wafer carrier loaded into the first housing, and
wherein the second substrate transfer apparatus comprises:
a second housing having a third opening at a position that overlaps with the second opening in a second direction perpendicular to the first direction, and a fourth opening at a position different from the third opening in the first direction, and
a second lifter configured to transfer the wafer carrier loaded into the second housing.

2. The substrate transfer system according to claim 1, further comprising:
a transfer device configured to transfer the wafer carrier into the first substrate transfer apparatus,
wherein the transfer device is configured to lower the wafer carrier to a position spaced apart from the first opening in the second direction and load the wafer carrier into the first substrate transfer apparatus.

3. The substrate transfer system according to claim 1, wherein the first lifter is configured to perform at least one of:
transfer the wafer carrier in the second direction within the first housing,
transfer the wafer carrier in the first direction within the first housing, and
at a position where the second opening and the third opening overlap with each other in the second direction, transfer the wafer carrier in the second direction through the second opening and the third opening.

4. The substrate transfer system according to claim 3, wherein the second lifter is configured to perform at least one of:
transfer the wafer carrier in the second direction, and
transfer in the first direction, the wafer carrier lifted from a lower surface of the second housing.

5. The substrate transfer system according to claim 2, further comprising:
a controller configured to control at least one of the transfer device, the first substrate transfer apparatus, or the second substrate transfer apparatus.

6. The substrate transfer system according to claim 5, wherein
each of the first substrate transfer apparatus and the second substrate transfer apparatus further comprises:
a first seating plate and a second seating plate, and
a first seating sensor and a second seating sensor configured to sense whether the first seating plate and the second seating plate are available, and
wherein the controller is further configured to:
determine an availability of the first seating plate or the second seating plate based on output data of the first seating sensor or the second seating sensor, and
control at least one of the transfer device or the first lifter based on the determined availability of the first seating plate or the second seating plate.

7. The substrate transfer system according to claim 6, wherein the controller is further configured to:
in response to determining that the wafer carrier is not seated based on the output data sensed by the first seating sensor, control the transfer device to operate, and
in response to determining that the wafer carrier is not seated based on the output data sensed by the second seating sensor, control the first lifter to operate.

8. The substrate transfer system according to claim 5, further comprising:
an event sensor configured to sense an event signal,
wherein the first substrate transfer apparatus and the second substrate transfer apparatus include a first damper and a second damper, respectively, and
wherein the controller is configured to control the first damper or the second damper to close the second opening or the fourth opening based on the event signal sensed by the event sensor.

9. The substrate transfer system according to claim 8, wherein
the first substrate transfer apparatus and the second substrate transfer apparatus comprise a first damper holder and a second damper holder, respectively,
wherein the first damper holder is configured to keep the first damper in a state of opening the second opening,
wherein the second damper holder is configured to keep the second damper in a state of opening the fourth opening, and
wherein the controller is configured to control, based on the event signal, the first damper holder to release the first damper from the state of opening the second opening or control the second damper holder to release the second damper from the state of opening the fourth opening.

10. A substrate transfer apparatus, comprising:
a housing including an first surface having an first opening thereon, and a second surface having a second opening thereon at a position spaced apart from the first opening in a first direction; and
a lifter coupled to the first surface of the housing from an inside of the housing,
wherein the lifter is configured to:
transfer a wafer carrier in the first direction or in a second direction perpendicular to the first direction,
transfer out the wafer carrier, introduced through the first opening, through the second opening, or transfer in the wafer carrier through the second opening.

11. The substrate transfer apparatus according to claim 10, wherein the lifter comprises:
a fixed plate coupled to the first surface of the housing,
a movable plate configured to move in the first direction from the fixed plate,
a driving device configured to move the movable plate from the fixed plate, and
a gripper configured to clamp the wafer carrier and move the wafer carrier in the second direction from the movable plate.

12. The substrate transfer apparatus according to claim 11, wherein
the lifter further comprises:
a drum disposed on the movable plate and rotatable, and
a cable with a first end coupled to the drum and wound around an outer circumferential surface of the drum and a second end connected to the gripper, and
wherein the gripper is movable in the second direction by rotation of the drum.

13. The substrate transfer apparatus according to claim 11, wherein the driving device comprises:
a first guide rail coupled to one of the movable plate or the fixed plate and configured to guide the movable plate to move in the first direction, and
a second guide rail coupled to the other one of the movable plate or the fixed plate.

14. The substrate transfer apparatus according to claim 10, comprising:
a damper configured to open and close the second opening, wherein a fixed end of the damper is rotatably coupled to the second surface of the housing; and
a damper holder configured to fix the damper in a state of opening the second opening.

15. The substrate transfer apparatus according to claim 14, wherein the damper holder is on one third surface of the housing to fix a free end of the damper,
wherein the one third surface of the housing is perpendicular to the first surface of the housing.

16. The substrate transfer apparatus according to claim 14, wherein
the damper comprises a magnetic material, and
the damper holder comprises an electromagnet.

17. The substrate transfer apparatus according to claim 10, wherein
the wafer carrier comprises a guide groove on a surface of the wafer carrier, and
the housing comprises a seating plate with a position guide thereon, and
wherein the position guide is inserted into the guide groove to guide a seating position of the wafer carrier.

18. The substrate transfer apparatus according to claim 17, wherein the substrate transfer apparatus further comprises:
a seating sensor disposed on the seating plate to sense whether the wafer carrier is seated on the seating plate, and
a controller configured to receive sensed data from the seating sensor, determine whether the wafer carrier is seated on the seating plate based on the sensed data, and control the lifter based on determining whether the wafer carrier is seated on the seating plate.

19. A substrate transfer system, comprising:
a first substrate transfer apparatus configured to transfer a wafer carrier, the first substrate transfer apparatus comprising a first seating sensor configured to sense whether the wafer carrier is seated;
a second substrate transfer apparatus below the first substrate transfer apparatus, the second substrate transfer apparatus configured to transfer the wafer carrier, the second substrate transfer apparatus comprising a second seating sensor configured to sense whether the wafer carrier is seated;
a transfer device configured to transfer the wafer carrier into the first substrate transfer apparatus; and
a controller configured to control at least one of the transfer device, the first substrate transfer apparatus, or the second substrate transfer apparatus based on output data of the first seating sensor or the second seating sensor,
wherein the first substrate transfer apparatus further comprises:
a first housing having a first opening and a second opening at a position different from the first opening in a first direction, and
a first lifter configured to transfer the wafer carrier loaded into the first housing, and
wherein the second substrate transfer apparatus comprises:
a second housing having a third opening at a position that overlaps with the second opening in a second direction perpendicular to the first direction, and a fourth opening at a position different from the third opening in the first direction, and
a second lifter configured to transfer the wafer carrier loaded into the second housing, and
wherein the controller is further configured to:
determine whether the wafer carrier is seated based on the output data of the first seating sensor or the second seating sensor,
in response to determining that the wafer carrier is not seated based on the output data sensed by the first seating sensor, control the transfer device to transfer the wafer carrier into the first housing, and
in response to determining that the wafer carrier is not seated based on the output data sensed by the second seating sensor, control the first lifter to transfer the wafer carrier into the second housing.

20. The substrate transfer system according to claim 19, further comprising:
an event sensor configured to sense an event signal; and
a damper configured to open and close the second opening, wherein a fixed end of the damper is rotatably coupled to a surface of the first housing; and
an electromagnet configured to fix the damper such that the damper selectively opens and closes the second opening, wherein
the controller is further configured to adjust an intensity of a current flowing through the electromagnet based on the event signal sensed by the event sensor.
